(19) United States
(12) Patent Application Publication
(10) Pub. No.: US 2005/0223982 A1
(43) Pub. Date: Oct. 13, 2005

(54) Apparatus and method for depositing thin film on wafer using remote plasma

(76) Inventors: Young Hoon Park, Kyungki-do (KR); Hong Joo Lim, Kyungki-do (KR); Sang Kyu Lee, Kyungki-do (KR); Hyun Soo Kyung, Kyungki-do (KR); Jang Ho Bae, Kyungki-do (KR)

Correspondence Address: CANTOR COLBURN, LLP, 55 GRIFFIN ROAD SOUTH, BLOOMFIELD, CT, 06002, US

(21) Appl. No.: 10/511,883

(22) PCT Filed: Apr. 17, 2003
(86) PCT No.: PCT/KR03/00786

§ 371 Date: Oct. 19, 2004

(30) Foreign Application Priority Data
Apr. 19, 2002 (KR) 10-2002-0021554

(51) Int. Cl. C23C 16/00

(52) U.S. Cl. 118/715; 427/255.23

(57) ABSTRACT

A remote-plasma ALD apparatus includes a reaction chamber, an exhaust line for exhausting gas from the reaction chamber, a first reactive gas supply unit for selectively supplying a first reactive gas to the reactant chamber or the exhaust line, a first reactive gas transfer line for connecting the first reactive gas supply unit and the reactant chamber, a first bypass line for connecting the first reactive gas supply line and the exhaust line, a radical supply unit for generating radicals and selectively supplying the radicals to the reactant chamber or the exhaust line, a radical transfer line for connecting the radical supply unit and the reactant chamber, a second bypass line for connecting the radical supply unit and the exhaust line, and a main purge gas supply unit for supplying a main purge gas to the first reactant transfer line and/or the radical transfer line.

### Technical Field

The present invention relates to an atomic film deposition (ALD) apparatus and an ALD method for depositing a thin film on a wafer such as a semiconductor substrate, and more particularly, to an ALD apparatus and an ALD method for depositing a thin film on a wafer, using remote plasma.

### BACKGROUND ART

An apparatus for depositing a thin film is used to form a predetermined thin film on a wafer loaded in a reaction chamber, by supplying reactive gases to the wafer. Such apparatuses are chemical vapor deposition (CVD) apparatuses, ALD apparatuses, and the like and are being applied in various techniques of fabricating semiconductor devices.

The CVD method enables a higher deposition rate as compared to the ALD method. However, the ALD method has advantages of lower process temperature, better step coverage, and higher degree of purity of a thin film as compared to the CVD method. So far, techniques of producing an apparatus for depositing a thin film adopting the advantages of both the CVD-type and ALD-type apparatuses have been developed.

### DISCLOSURE OF THE INVENTION

The present invention provides an ALD apparatus and an ALD method for depositing a thin film using remote plasma, by which a thin film having a good step coverage and a high degree of purity can be deposited at high speed at a low process temperature.

In accordance with an aspect of the present invention, there is provided a remote-plasma ALD apparatus comprising a reaction chamber 100 in which wafers are loaded, an exhaust line 200 for exhausting gas from the reaction chamber 100, a first reactive gas supply unit 310 for selectively supplying a first reactive gas to the reactant chamber 100 or the exhaust line 200, a first reactive gas transfer line 320 for connecting the first reactive gas supply unit 310 and the reactant chamber 100, a first bypass line 330 for connecting the first reactive gas supply line 310 and the exhaust line 200, a radical supply unit 340 for generating corresponding radicals by applying plasma to a second reactive gas and then selectively supplying the radicals to the reactant chamber 100 or the exhaust line 200, a radical transfer line 350 for connecting the radical supply unit 340 and the reactant chamber 100, a second bypass line 360 for connecting the radical supply unit 340 and the exhaust line 200, and a main purge gas supply unit 370 for supplying a main purge gas to the first reactant transfer line 320 and/or the radical transfer line 350.

In the present invention, the first reactive gas supply unit 310 comprises a source container 311 filled with a predetermined amount of liquid first reactant which will be the first reactive gas, a first mass flow controller (hereinafter, referred to as an “MFC 1”) for controlling the flow rate of an inert gas fed into the source container 311, and a first path conversion unit 316 for enabling the inert gas or the first reactive gas to selectively flow into the first reactive gas transfer line 320 or the first bypass line 330.

In the present invention, the radical supply unit 340 comprises a second mass flow controller (hereinafter, referred to as an “MFC 2”) for controlling the flow rate of the second reactive gas, a third mass flow controller (hereinafter, referred to as an “MFC 3”) for controlling the flow rate of the inert gas, a remote plasma generator 341 into which the second reactive gas and/or the inert gas are fed by way of the MFC 2 and the MFC 3 and for generating corresponding radicals by applying plasma to the second reactive gas, and a second path conversion unit 346 for enabling the generated radicals to selectively flow into the radical transfer line 350 and/or the second bypass line 360. Preferably, the radical supply unit 340 further comprises a third bypass line 380 for enabling the second reactive gas to selectively flow through the MFC 2 into the second bypass line 360.

In the present invention, the main purge gas supply unit 370 comprises an MFC 4 for controlling the flow rate of the main purge gas and a third path conversion unit 376 for enabling the main purge gas to flow into the first reactive gas transfer line 320 or the radical transfer line 350.

In accordance with another aspect of the present invention, there is an ALD method for depositing a thin film using the foregoing remote-plasma ALD apparatus.

According to a first embodiment of the present invention, the method for depositing a thin film using remote plasma comprises forming a thin film on a substrate loaded in the reaction chamber 100 by repeatedly performing a first reactive gas feeding step (S1) in which the first reactive gas is fed into the reactant chamber 100 and a first reactive gas purge step (S2) in which the first reactive gas, fed into the reactant chamber 100, is purged, in a state where a luffing valve 210 positioned between the reactant chamber 100 and the exhaust line 200 remains open, gases flowing through an inner point A of the first path conversion unit 316 and an inner point B of the second path conversion unit 346 continue to flow into the reactant chamber 100 or bypass lines, and radicals are fed into the reactant chamber 100.

In the present invention, after depositing a thin film, radicals and an inert gas are injected into the reactant chamber 100 to thermally treat the thin film. The radicals are formed of at least one selected from the group consisting of O, N, H, OH, and NH and a combination thereof.

According to a second embodiment of the present invention, the method for depositing a thin film using remote plasma comprises forming a thin film on a substrate loaded in a reaction chamber by repeatedly performing a radical feeding step (S3) in which radicals are fed into the reactant chamber 100, a radical purge step (S4) in which the radicals are purged from the reaction chamber 100, a first reactive gas feeding step (S1) in which the first reactive gas is fed into the reactant chamber 100, and a first reactive gas purge step (S2) in which the first reactive gas, fed into the reactant chamber 100, is purged, in a state where a luffing valve 210 positioned between the reactant chamber 100 and the exhaust line 200 remains open, and gases flowing through an inner point A of the first path conversion unit 316, an inner point B of the second path conversion unit 346, and an inner point C of the third path conversion unit 376 continue to flow into the reactant chamber 100 or bypass lines.

The radical purge step (S4) comprises injecting the main purge gas, the flow rate of which is controlled by the MFC 4 of the main purge gas supply unit 370, into the reaction chamber 100 by way of the radical transfer line 350.

In the present invention, the sum of the flow rate of the inert gas flowing through the first reactive gas transfer line 320 and the radical transfer line 350 is maintained at a constant level during the first reactive gas purge step (S2).

In the present invention, after depositing a thin film, radicals and an inert gas are injected into the reactant chamber 100 to thermally treat the thin film. The radicals are formed of at least one selected from the group consisting of O, N, H, OH; and NH and a combination thereof.

According to a third embodiment of the present invention, the method for depositing a thin film using remote plasma comprises forming a thin film on a substrate loaded in the reaction chamber 100 by repeatedly performing a radical feeding step (S3) in which radicals are fed into the reaction chamber 100, a radical purge step (S4′) in which the radicals are purged from the reaction chamber 100, a first reactive gas feeding step (S1) in which a first reactive gas is fed into the reaction chamber 100, and a first reactive gas purge step (S2) in which the first reactive gas is purged from the reactant chamber 100, in a state where a luffing valve 210 positioned between the reactant chamber 100 and the exhaust line 200 remains open and gases flowing through an inner point A of the first path conversion unit 316 and an inner point D of the radical supply unit 340 continue to flow into the reactant chamber 100 or bypass lines.

The radical purge step (S4′) comprises injecting only the inert gas (excluding the second reactive gas), the flow rate of which is controlled by the MFC 3 of the radical supply unit, into the reaction chamber 100 by way of the radical transfer line 350.

In the present invention, the sum of the flow rate of the inert gas flowing through the first reactive gas transfer line 320 and the radical transfer line 350 is maintained at a constant level during the first reactive gas purge step (S2).

In the present invention, after depositing a thin film, radicals and an inert gas are injected into the reactant chamber 100 to thermally treat the thin film. The radicals are formed of at least one selected from the group consisting of O, N, H, OH, and NH and a combination thereof.

### BRIEF DESCRIPTION OF THE DRAWINGS

FIG. 1 is a construction diagram of a remote-plasma ALD apparatus according to the present invention;

FIG. 2 is a partial perspective view of a remote plasma generator used in the ALD apparatus of FIG. 1;

FIG. 3 is a graph for explaining a method for depositing a thin film using the ALD apparatus of FIG. 1, according to a first embodiment of the present invention;

FIG. 4 is a graph for explaining a method for depositing a thin film using the ALD apparatus of FIG. 1, according to a second embodiment of the present invention; and

FIG. 5 is a graph for explaining a method for depositing a thin film using the ALD apparatus of FIG. 1, according to a third embodiment of the present invention.

### BEST MODE FOR CARRYING OUT THE INVENTION

Hereinafter, the present invention will now be described more fully with reference to the accompanying drawings, in which preferred embodiments of the invention are shown. This invention may, however, be embodied in many different forms and should not be construed as being limited to the embodiments set forth herein.

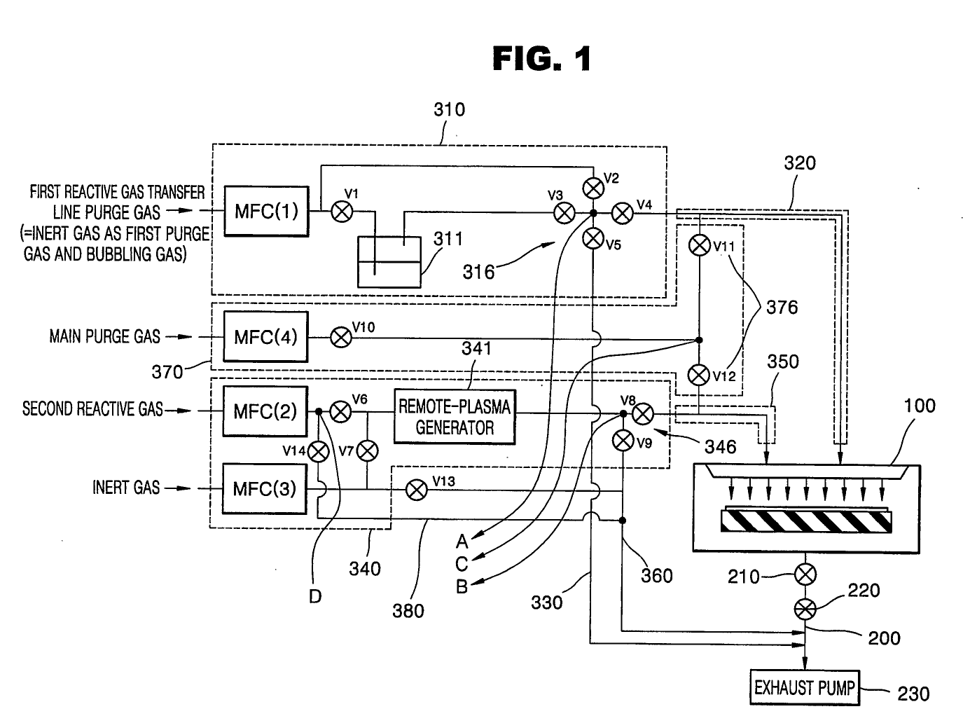

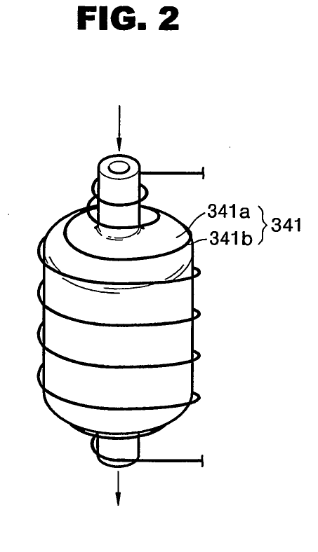

FIG. 1 is a construction diagram of a remote-plasma ALD apparatus according to the present invention. FIG. 2 is a partial perspective view of a remote plasma generator used in the ALD apparatus of FIG. 1.

Referring to FIGS. 1 and 2, the remote-plasma ALD apparatus according to the present invention comprises a reaction chamber 100 where wafers w are loaded and deposited, an exhaust line 200 for exhausting gas from the reaction chamber 100, and a gas jungle for selectively supplying a reactive gas and/or an inert gas to the reactant chamber 100 or the exhaust line 200.

The reactant chamber 100 enables deposition of a thin film on a substrate using a known shower-head type or flow type.

The exhaust line 200, which is used to exhaust a reactive gas from the reaction chamber 100, is where a luffing valve 210, a throttle valve 220, and an exhaust pump 230 are installed.

The gas jungle comprises a first reactive gas supply unit 310 for selectively supplying a first reactive gas to the reaction chamber 100 or the exhaust line 200, a first reactive gas transfer line 320 for connecting the first reactive gas supply unit 310 and the reaction chamber 100, a first bypass line 330 for connecting the first reactive gas supply unit 310 and the exhaust line 200, a radical supply unit 340 for generating corresponding radicals by applying plasma to a second reactive gas and selectively supplying the radicals to the reaction chamber 100 or the exhaust line 200, a radical transfer line 350 for connecting the radical supply unit 340 and the reaction chamber 100, a second bypass line 360 for connecting the radical supply unit 340 and the exhaust line 200, and a main purge gas supply unit 370 for supplying a main purge gas to the first reactive gas transfer line 320 and/or the radical transfer line 350. The gas jungle further comprises a third bypass line 380 for enabling the second reactive gas to selectively flow into the second bypass line 360 by way of an MFC 2.

The first reactive gas supply unit 310 enables the flow-rate-controlled first reactive gas to selectively flow into the reaction chamber 100 or the exhaust line 200. The first reactive gas supply unit 310 comprises a source container 311 filled with a predetermined amount of liquid first reactant which will be the first reactive gas, an MFC 1 for controlling the flow rate of an inert gas fed into the source container 311, and a first path conversion unit 316 for enabling the inert gas or the first reactive gas to selectively flow into the first reactive gas transfer line 320 or the first bypass line 330.

The MFC 1 is used to control the flow rate of the inert gas, which bubbles the liquid first reactant. Here, a first valve V1 is installed between the MFC 1 and the source container 311 to control the flow rate of the inert gas.

The first path conversion unit 316 includes a second valve V2, a third valve V3, a fourth valve V4, and a fifth valve V5, which are adjacent to one another. The first path conversion unit 316 enables the inert gas or the first reactive gas, which flows through an inner point A where the second through fifth valves V2, V3, V4, and V5 come across, to selectively flow into the first reactive gas transfer line 320 or the first bypass line 330.

In the present embodiment, the first reactive gas supply unit 310 is structured such that the first reactive gas is generated by bubbling the liquid first reactant. However, it is possible to produce the first reactive gas supply unit 310 as a liquid delivery system (LDS) or a direct liquid injection (DLI) structure.

The radical supply unit 340 is where radicals to be supplied to the reaction chamber 100 are generated. The radical supply unit 340 comprises an MFC 2 for controlling the flow rate of the second reactive gas, an MFC 3 for controlling the flow rate of the inert gas, a remote-plasma generator 341 into which the second reactive gas and/or the inert gas flow by way of the MFC 2 and the MFC 3 and for generating corresponding radicals by applying plasma to the second reactive gas, and a second path conversion unit 346 for enabling the generated radicals to selectively flow into the radical transfer line 350 and/or the second bypass line 360. Here, a sixth valve V6 is installed between the MFC 2 and the remote-plasma generator 341, and a seventh valve V7 is installed between the MFC 3 and the remote-plasma generator 341.

As shown in FIG. 2, the remote-plasma generator 341 includes a ceramic tube 341a where the second reactive gas flows and an RF coil 341b wound around the ceramic tube 341a. An RF power of 13.56 MHz is applied to the RF coil 341b. The RF power ionizes and activates the second reactive gas flowing through the ceramic tube 341a, thereby generating plasma particles, i.e., radicals. That is, the remote-plasma generator 341 is used to apply electric energy to the second reactive gas fed into the ceramic tube 341a and increase activated energy.

It is possible that only the second reactive gas is supplied to the remote-plasma generator 341. However, in the present invention, a gas mixture of the flow-rate-controlled second reactive gas and the flow-rate-controlled inert gas is supplied to the remote-plasma generator 341 in order to widen the width of a process window.

The second path conversion unit 346 includes an eighth valve V8 and a ninth valve V9 and enables the inert gas or the radicals, which flow through an inner point B where the eighth valve V8 and the ninth valve V9 come across, to selectively flow into the radical transfer line 350 or the second bypass line 360. The diameter of the opening of the eighth valve V8 must be sufficiently large. In doing so, when the eighth valve V8 is open and the radicals flow through the eighth valve V8, the activated energy of the radicals can be maintained at a constant level.

The radical transfer line 350 is used to transfer the radicals generated in the remote-plasma generator 341 to the reaction chamber 100. The radical transfer line 350 must be structured such that its pipe has a sufficient diameter and as short a length as possible. Thus, the activated energy of the radicals can be maintained at a constant level.

The main purge gas supply unit 370 enables a main purge gas (e.g. inert gas) to selectively flow into the first reactive gas transfer line 320 or the radical transfer line 350. In the present embodiment, when the first reactive gas or the radicals are bypassed to the exhaust line 200, an inert gas is supplied to the first reactive gas transfer line 320 or the radical transfer line 350. The main purge gas supply unit 370 comprises a fourth mass flow control unit (hereinafter, referred to as an “MFC 4”) for controlling the flow rate of the main purge gas, a third path conversion unit 376 for enabling the main purge gas to selectively flow into the first reactive gas transfer line 320 or the radical transfer line 350, and a tenth valve V10 installed between the MFC 4 and the third path conversion unit 376.

The third path conversion unit 376 includes an eleventh valve V11 and a twelfth valve V12 and enables the main purge gas, which flows through an inner point C where the eleventh valve V11 and the twelfth V12 come across, to selectively flow into the first reactive gas transfer line 320 or the radical transfer line 350.

Also, a thirteenth valve V13 is installed between the MFC 3 and the second bypass line 360, and a fourteenth valve V14 is installed in the third bypass line 380.

The valves V1 through V14 are coupled to and controlled by a controller (not shown).

The remote-plasma ALD apparatus having the foregoing structure can improve a low deposition rate, which is a disadvantage of a typical ALD apparatus, and reduce the process temperature by using electric energy.

Hereinafter, a first reactive gas feeding step, a first reactive gas purge step, a radical feeding step, and a radical purge step will be briefly described.

a) First Reactive Gas Feeding Step (S1)

The inert gas is flow-rate-controlled by the MFC 1 and is fed through the first valve V1 into the source container 311. The inert gas bubbles the liquid first reactive source stored in the source container 311 to generate the first reactive gas. The first reactive gas flows through the third valve V3 and the fourth valve V4 together with the bubbling gas and is fed through the first reactive gas transfer line 320 into the reaction chamber 100.

b) Second Reactive Gas Purge Step (S2)

After the inert gas is flow-rate-controlled by the MFC 1, the inert gas flows through the second valve V2 and the fourth valve V4 and is fed through the first reactive gas transfer line 320 into the reaction chamber 100. Because the purge gas (e.g. inert gas) does not flow through the source container 311, the first reactive gas is not generated. Thus, only the purge gas is injected into the reaction chamber 100 and purges the first reactive gas included in the reaction chamber 100.

c) Radical Feding Step (S3)

The second reactive gas and the inert gas are flow-rate-controlled by the MFC 2 and the MFC 3, respectively, and then are injected into the remote-plasma generator 341 through the opened sixth valve V6 and seventh valve V7, respectively. A gas mixture of the second reactive gas and an inert gas is converted into a plasma gas to be radicals while flowing through the remote-plasma generator 341. In this step, the resultant radicals flow through the eighth valve V8 and are injected into the reaction chamber 100 through the radical transfer line 350.

In the present embodiment, a gas mixture of the second reactive gas and the inert gas is supplied to the remote-plasma generator 341 in order to widen the width of a process window. However, it is also possible to supply only the second reactive gas.

d) Radical Purge Step (S4)

By closing the eighth valve V8 and opening the ninth valve V9, the radicals are not injected into the reaction chamber 100 and flow through the second bypass line 360 into the exhaust pump 230 of the exhaust line 200, and the main purge gas, supplied from the main purge gas supply unit 370, flows through the radical transfer line 350 into the reaction chamber 100. That is, the radicals are no longer supplied into the radical transfer line 350, and the main purge gas, flow-rate-controlled by the MFC 4, flows through the tenth valve V10, the twelfth valve V12, and the radical transfer line 350 into the reaction chamber 100.

e) Radical Purge Step (S4′)

By closing the sixth valve V6 and opening the fourteenth valve V14, the second reactive gas flows through the third bypass line 380 into the exhaust pump 230 of the exhaust line 200, and the inert gas, flow-rate-controlled by the MFC 3, flows through the remote-plasma generator 341 and the eighth valve V8 into the reaction chamber. That is, because the second reactive gas is exhausted through the third bypass line 380 and the second bypass line 360, the second reactive gas is not injected into the remote-plasma generator 341. Thus, only the inert gas flowing through the MFC 3 is fed into the reaction chamber 100, thereby purging the radicals from the reaction chamber 100.

Hereinafter, embodiments of a method for depositing a thin film using the foregoing ALD apparatus will be described.

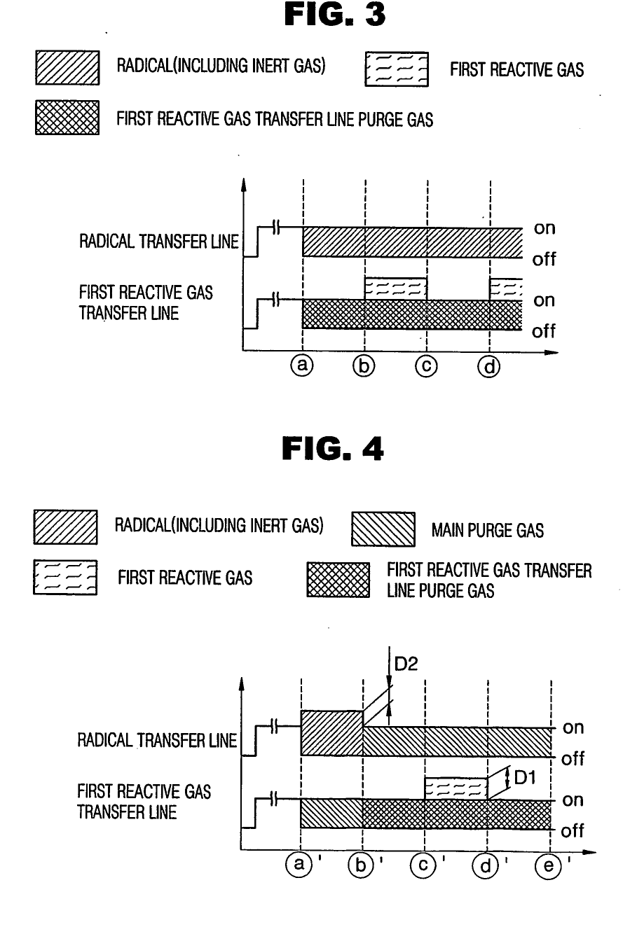

FIG. 3 is a graph for explaining a method for depositing a thin film using the ALD apparatus of FIG. 1, according to a first embodiment of the present invention. In the first embodiment, a substrate is loaded in the reaction chamber 100. In a state where a luffing valve 210 positioned between the reaction chamber 100 and the exhaust line 200 remains open and radicals continue to be fed into the reaction chamber 100, the first reactive gas feeding step (S1) and the first reactive gas purge step (S2) are repeatedly performed. As a result, a thin film is deposited on the substrate loaded in the reaction chamber 100.

In other words, as shown in interval â-\hat{b} of FIG. 3, while the radicals continue to be fed into the reaction chamber 100, the purge gas, flow-rate-controlled by the MFC 1, flows through the second valve V2 and the fourth valve V4 into the reaction chamber 100 by way of the first reactive gas transfer line 320.

Next, as shown in interval (\hat{b}-ĉ, the first reactive gas feeding step (S1) is performed. In a state where the radicals continue to be fed into the reaction chamber 100, the first reactive gas, which is obtained by injecting the inert gas flow-rate-controlled by the MFC 1 into the source container 311 and bubbling the inert gas, flows through the third valve V3 and the fourth valve V4 into the reaction chamber 100.

Next, as shown in interval (ĉ-\hat{d}, in a state where the radicals continue to be fed into the reaction chamber 100, the foregoing first reactive gas purge step (S2) and the first reactive gas feeding step (S1) are repeatedly performed.

In other words, in a state where the radicals continue to be fed into the reaction chamber 100, the first reactive gas purge step (S2) and the first reactive gas feeding step (S1) are repeated one or more times, thereby depositing a thin film on the substrate loaded in the reaction chamber 1 00.

Here, a gas flowing through the inner point A of the first path conversion unit 316 continues to flow into the reaction chamber 100 or the first bypass line 330, while a gas flowing through the inner point B of the second path conversion unit 346 continues to flow into the reaction chamber 100 or the second bypass line 360.

In the present invention, a thin film is deposited on the substrate using the ALD apparatus in a state where the radicals continue to be fed into the reaction chamber without being purged. Accordingly, a process pressure in the reaction chamber 100 can be maintained at a constant level, and the thin film can be uniformly formed.

Meanwhile, after depositing a thin film, radicals and an inert gas may be injected into the reaction chamber 100 to thermally treat the thin film. The radicals may be formed of at least one selected from the group consisting of O, N, H, OH, and NH and a combination thereof. To supply such radicals, the second reactive gas may be O₂, O₃, H₂, NH₃, or N₂. For example, in a case where a TiCl₄ gas is used to deposit a thin film and H₂ is used as the second reactive gas, if radicals including hydrogen atoms are injected into the reaction chamber after depositing a thin film, the concentration of impurity ions (Cl) included in the thin film can be reduced, thus improving the degree of purity of the thin film. Alternatively, when an Al₂O₃ thin film is deposited using a TMA gas, O₂, H₂O, or O₃ may be used as the second reactive gas. Also, to deposit a metal thin film using Ti, TiN, Al, or Cu, a metal organic gas may be used as the first reactive gas and H₂ may be used as the second reactive gas. In these cases, the second reactive gas is injected onto the thin film, which is deposited in a state of radicals during a thermal treatment, so as to improve the degree of purity of the thin film.

Hereinafter, a second embodiment of the method for depositing a thin film using the ALD apparatus will be described. FIG. 4 is a graph for explaining the method for depositing a thin film using the ALD apparatus of FIG. 1, according to the second embodiment of the present invention.

In the present embodiment, a substrate is loaded in the reaction chamber 100. In a state where the luffing valve 210 positioned between the reaction chamber 100 and the exhaust line 200 is open, the radical feeding step (S3) in which radicals are fed into the reaction chamber 10O, the radical purge step (S4) in which the radicals are purged from the reaction chamber 10O, the first reactive gas feeding step (S1) in which the first reactive gas is fed into the reaction chamber 100, and the first reactive gas purge step (S2) in which the first reactive gas is purged from the reaction chamber 100 are repeatedly performed. As a result, a thin film is formed on the substrate loaded in the reaction chamber 100.

As shown in interval â′-\hat{b}′, the radical feeding step (S3), in which radicals generated in the radical supply unit 340 are fed into the reaction chamber 10O, is performed. Here, by opening the tenth valve V10 and the eleventh valve V11, a main purge gas (e.g., inert gas), flow-rate-controlled by the MFC 4, can flow through the reactive gas transfer line 320 into the reaction chamber 100.

Next, as shown in interval \hat{b}′-ĉ′, the radical purge step (S4) is performed. In this step, by closing the eleventh valve V11 and the twelfth valve V12, the main purge gas, flow-rate-controlled by the MFC 4, can flow through the radical transfer line 350 into the reaction chamber 100. Here, by closing the eighth valve V8 and opening the ninth valve V9, the radicals, generated in the radical supply unit 34O, flow through the second bypass line 360 into the exhaust line 200 without flowing into the reaction chamber 100.

Next, as shown in interval ĉ′-\hat{d}′, the first reactive gas feeding step (S1), in which the first reactive gas is fed into the reaction chamber 100, is performed. As described above, the first reactive gas, which is obtained by feeding a bubbling gas flow-rate-controlled by the MFC 1 into the source container 311, flows together with the bubbling gas through the third valve V3 and the fourth valve V4 into the reaction chamber 100. Here, the main purge gas continues to be fed into the reaction chamber 100 by way of the radical transfer line 350.

Next, as shown in interval \hat{d}′-ê′, the first reactive gas purge step (S2), in which the first reactive gas is purged from the reaction chamber 100, is performed. Here, the main purge gas continues to be fed into the reaction chamber 100 by way of the radical transfer line 350.

That is, the foregoing steps are repeated one or more times until a thin film is deposited on the substrate loaded in the reaction chamber 100. Here, gases flowing through the inner point A of the first path conversion unit 316, the inner point B of the second path conversion unit 346, and the inner point C of the third path conversion unit 376 continue to flow into the reaction chamber 100 or the bypass lines.

According to the present embodiment, because the radical feeding step (S3) and the radical purge step (S4) are alternately repeated, the degree of purity of the thin film may be better than in the case of the first embodiment. However, since the process pressure in the reaction chamber 100 may be changed within a relatively large range, the uniformity of the thin film may be degraded. Therefore, to uniformly form a thin film, the sum of the flow rates of gases injected onto the substrate loaded in the reaction chamber should be maintained at a constant level and the luffing valve 210 should not be turned on/off except during the reactive gas feeding step (S1).

Accordingly, to maintain the process pressure in the reaction chamber 100 at a constant level, the MFC 1 and the MFC 4 are set to allow the same flow rate. Also, the flow rate of the first reactive gas or the second reactive gas, which is fed into the reaction chamber 100, is adjusted to be smaller than the flow rate of the purge gas. As shown in FIG. 4, as the flow rates of the first reactive gas and the second reactive gas become greater, the heights of D1 and D2 become higher. As a result, the pressure in the reaction chamber is changed within a large range. The flow rates of the first and second reactive gases fed into the reaction chamber 100 must be properly adjusted considering the uniformity of a thin film, the step coverage, the degree of purity of the thin film, and the like.

In the second embodiment, after depositing a thin film, radicals and an inert gas are injected into the reactant chamber 100 to thermally treat the thin film. The radicals are formed of at least one selected from the group consisting of O, N, H, OH, and NH and a combination thereof.

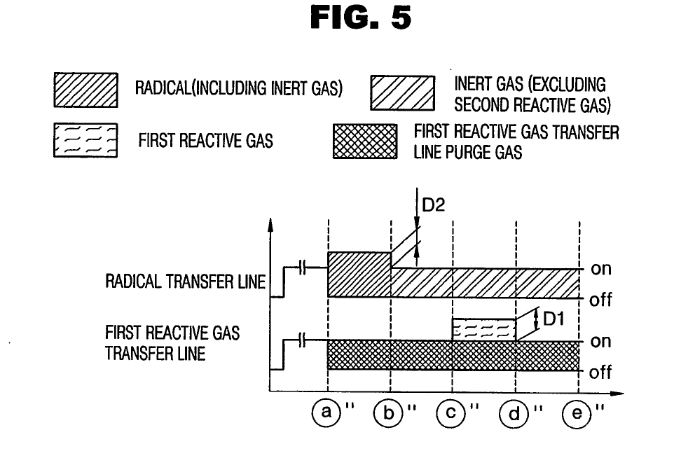

Hereinafter, a third embodiment of the method for depositing a thin film using the ALD apparatus will be described. FIG. 5 is a graph for explaining the method for depositing a thin film using the ALD apparatus of FIG. 1, according to the third embodiment of the present invention.

In the present embodiment, a substrate is loaded in the reaction chamber 100. In a state where the luffing valve 210 positioned between the reaction chamber 100 and the exhaust line 200 is open, the radical feeding step (S3) in which radicals are fed into the reaction chamber 100, a radical purge step (S4′) in which the radicals are purged form the reaction chamber 100, the first reactive gas feeding step (S1) in which the first reactive gas is fed into the reaction chamber 100, and the first reactive gas purge step (S2) in which the first reactive gas is purged from the reaction chamber 100 are repeatedly performed. As a result, a thin film is deposited on the substrate loaded in the reaction chamber 100.

As shown in interval â″-\hat{b}″ of FIG. 5, the radical feeding step (S3), in which radicals generated in the radical supply unit 340 are fed into the reaction chamber 100, is performed. Here, by opening the second valve V2 and the fourth valve V4, a purge gas (e.g. inert gas), flow-rate-controlled by the MFC 1, is fed into the reaction chamber 100 by way of the reactive gas transfer line 320.

Next, as shown in interval \hat{b}″-ĉ″, the radical purge step (S4′) is performed. In this step, by closing the sixth valve V6 and opening the fourteenth valve V14, the second reactive gas flows through the third bypass line 380 into the exhaust pump 230 of the exhaust line 200. Also, an inert gas, flow-rate-controlled by the MFC 3, flows through the remote-plasma generator 341 and the eighth valve V8 into the reaction chamber 100. Here, because the second reactive gas is exhausted through the third bypass line 380 and the second bypass line 360 and is not fed into the remote-plasma generator 341, radicals are not generated. As a result, only the inert gas (excluding the second reactive gas) flows through the MFC 3 into the reaction chamber 100, thereby purging the radicals from the reaction chamber 100.

Next, as shown in interval ĉ″-\hat{d}″, the first reactive gas feeding step (S1), in which the first reactive gas is fed into the reaction chamber 100, is performed. As described above, the first reactive gas, which is obtained by feeding a bubbling gas flow-rate-controlled by the MFC 1 into the source container 311, flows through the third valve V3 and the fourth valve V4 into the reaction chamber 100. Here, the bubbling gas (e.g. inert gas) flowing through the MFC 3 continues to be fed into the reaction chamber 100 by way of the radical transfer line 350.

Next, as shown in interval \hat{d}″-ê″, the first reactive gas purge step (S2), in which the first reactive gas is purged from the reaction chamber 100, is performed. Here, the purge gas flowing through the MFC 3 continues to be fed into the reaction chamber 100 by way of the radical transfer line 350.

That is, the foregoing steps are repeated one or more times until a thin film is deposited on a thin film loaded in the reaction chamber 100. Here, gases flowing through the inner point A of the first path conversion unit 316 and a point D where the third bypass line 380 of the radical supply unit 340 and the MFC 3 come across continue to flow into the reaction chamber 100 or the second bypass line 360.

The third embodiment of the present invention is a combination of the first embodiment and the second embodiment. When a thin film is deposited, the eighth valve V8 remains open and the ninth valve V9 remains closed such that a gas flowing through the remote-plasma generator 341 is necessarily fed into the reaction chamber 100. Here, in a state where an inert gas flowing through the seventh valve V7 is necessarily fed into the remote-plasma generator 341, while the sixth valve V6 and the fourteenth valve V14 are alternately opened and closed, the radical feeding step (S3) and the radical purge step (S4) are s repeatedly performed. That is, when the sixth valve V6 is open and the fourteenth valve V14 is closed, the radical feeding step (S3) is performed, and when the sixth valve V6 is closed and the fourteenth valve V14 is open, because the second reactive gas is not fed into the reaction chamber, the radical purge step (S4) is performed.

Then, during the first reactive gas feeding step (S1) and the first reactive gas purge step (S2), only the inert gas flows through the MFC 3, the seventh valve V7, the remote-plasma generator 341, and the eighth valve V8 into the reaction chamber 100 through the radical transfer line 350. Here, a description of D1 and D2 is the same as in the second embodiment and will be omitted here. Similarly, also in the present embodiment, after depositing a thin film, radicals and an inert gas may be injected into the reaction chamber 100 to thermally treat the thin film. The radicals may be formed of at least one selected from the group consisting of O, N, H, OH, and NH and a combination thereof. The thermal treatment can improve the degree of purity of the thin film.

While the present invention has been particularly shown and described with reference to preferred embodiments thereof, it will be understood by those of ordinary skill in the art that various changes in form and details may be made therein without departing from the spirit and scope of the present invention as defined by the following claims.

### Industrial Applicability

According to the present invention as described above, a thin film having a good step coverage and a high degree of purity can be deposited at high speed and at a low process temperature, using a remote-plasma ALD apparatus.

1. A remote-plasma atomic film deposition apparatus comprising:
a reaction chamber in which wafers are loaded;
an exhaust line for exhausting gas from the reaction chamber;
a first reactive gas supply unit for selectively supplying a first reactive gas to the reactant chamber or the exhaust line;
a first reactive gas transfer line for connecting the first reactive gas supply unit and the reactant chamber;
a first bypass line for connecting the first reactive gas supply line and the exhaust line;
a radical supply unit for generating corresponding radicals by applying plasma to a second reactive gas and then selectively supplying the radicals to the reactant chamber or the exhaust line;
a radical transfer line for connecting the radical supply unit and the reactant chamber;
a second bypass line for connecting the radical supply unit and the exhaust line; and
a main purge gas supply unit for supplying a main purge gas to the first reactant transfer line and/or the radical transfer line.

2. The apparatus of claim 1, wherein the first reactive gas supply unit comprises:
a source container filled with a predetermined amount of liquid first reactant which will be the first reactive gas;
an MFC 1 for controlling the flow rate of an inert gas fed into the source container; and
a first path conversion unit for enabling the inert gas or the first reactive gas to selectively flow into the first reactive gas transfer line or the first bypass line.

3. The apparatus of claim 1, wherein the radical supply unit comprises:
an MFC 2 for controlling the flow rate of the second reactive gas;
an MFC 3 for controlling the flow rate of the inert gas;
a remote plasma generator into which the second reactive gas and/or the inert gas are fed by way of the MFC 2 and the MFC 3 and for generating corresponding radicals by applying plasma to the second reactive gas; and
a second path conversion unit for enabling the generated radicals to selectively flow into the radical transfer line and/or the second bypass line.

4. The apparatus of claim 3, wherein the radical supply unit further comprises a third bypass line for enabling the second reactive gas to selectively flow through the MFC 2 into the second bypass line.

5. The apparatus of claim 1, wherein the main purge gas supply unit comprises:
an MFC 4 for controlling the flow rate of the main purge gas; and
a third path conversion unit for enabling the main purge gas to flow into the first reactive gas transfer line or the radical transfer line.

6. An atomic film deposition method using the remote-plasma atomic film deposition apparatus of claims 1, the method comprising:
forming a thin film on a substrate loaded in the reaction chamber by repeatedly performing a first reactive gas feeding step in which the first reactive gas is fed into the reactant chamber and a first reactive gas purge step in which the first reactive gas, fed into the reactant chamber, is purged, in a state where a luffing valve positioned between the reactant chamber and the exhaust line remains open, gases flowing through an inner point A of the first path conversion unit and an inner point B of the second path conversion unit continue to flow into the reactant chamber or bypass lines, and radicals are fed into the reactant chamber.

7. The method of claim 6, after depositing a thin film, further comprising injecting radicals and an inert gas into the reactant chamber to thermally treat the thin film, wherein the radicals are formed of at least one selected from the group consisting of O, N, H, OH, and NH and a combination thereof.

8. An atomic film deposition method using the remote-plasma atomic film deposition apparatus of claims 1, the method comprising:
forming a thin film on a substrate loaded in a reaction chamber by repeatedly performing a radical feeding step in which radicals are fed into the reactant chamber, a radical purge step in which the radicals are purged from the reaction chamber, a first reactive gas feeding step in which the first reactive gas is fed into the reactant chamber, and a first reactive gas purge step in which the first reactive gas, fed into the reactant chamber, is purged, in a state where a luffing valve positioned between the reactant chamber and the exhaust line remains open, and gases flowing through an inner point A of the first path conversion unit, an inner point B of the second path conversion unit, and an inner point C of the third path conversion unit continue to flow into the reactant chamber or bypass lines,
wherein the radical purge step comprises injecting the main purge gas, the flow rate of which is controlled by the MFC 4 of the main purge gas supply unit, into the reaction chamber by way of the radical transfer line.

9. The method of claim 8, wherein the sum of the flow rate of the inert gas flowing through the first reactive gas transfer line and the radical transfer line is maintained at a constant level during the first reactive gas purge step.

10. The method of claim 8, after depositing a thin film, further comprising injecting radicals and an inert gas into the reactant chamber to thermally treat the thin film, wherein the radicals are formed of at least one selected from the group consisting of O, N, H, OH, and NH and a combination thereof.

11. An atomic film deposition method using the remote-plasma atomic film deposition apparatus of claims 1, the method comprising:
forming a thin film on a substrate loaded in the reaction chamber by repeatedly performing a radical feeding step in which radicals are fed into the reaction chamber, a radical purge step in which the radicals are purged from the reaction chamber, a first reactive gas feeding step in which the first reactive gas is fed into the reaction chamber, and a first reactive gas purge step in which the first reactive gas is purged from the reactant chamber, in a state where a luffing valve positioned between the reactant chamber and the exhaust line remains open and gases flowing through an inner point A of the first path conversion unit and an inner point D of the radical supply unit continue to flow into the reactant chamber or bypass lines,
wherein the radical purge step comprises injecting only the inert gas (excluding the second reactive gas), the flow rate of which is controlled by the MFC 3 of the radical supply unit, into the reaction chamber by way of the radical transfer line.

12. The method of claim 11, wherein the sum of the flow rate of the inert gas flowing through the first reactive gas transfer line and the radical transfer line is maintained at a constant level during the first reactive gas purge step.

13. The method of claim 13, after depositing a thin film, further comprising injecting radicals and an inert gas into the reactant chamber to thermally treat the thin film, wherein the radicals are formed of at least one selected from the group consisting of O, N, H, OH, and NH and a combination thereof.
